(19) United States
(12) Patent Application Publication
(10) Pub. No.: US 2006/0046203 A1
(43) Pub. Date: Mar. 2, 2006

(54) Method for producing a thin film transistor and a device of the same

(76) Inventors: Lin-En Chou, Kao Hsiung Hsien (TW); Chia-Hao Tsai, Chungho City (TW); Shun-Feng Liu, Tao Yuan City (TW)

Correspondence Address: RABIN & BERDO, P.C., Suite 500, 1101 14 Street, N.W., Washington, DC, 20005, US

(21) Appl. No.: 10/995,479

(22) Filed: Nov. 24, 2004

(30) Foreign Application Priority Data
Aug. 31, 2004 (TW) 93126251

(51) Int. Cl. G03F 7/00

(52) U.S. Cl. 430/319; 430/328

(57) ABSTRACT

A method for producing a thin film transistor and including the following steps for preparing a glass substrate; having a negative photosensitive coating on the glass substrate; providing a transparent mold plate, having a plurality of opaque protrusions in accordance with a predetermined pattern; controlling the transparent mold plate downwardly to press into the negative photosensitive coating of the glass substrate; curing a part of the negative photosensitive coating, which is shielded by the protrusions and shaped corresponding to the predetermined pattern, via an explosion by a UV light; separating the transparent mold plate from the glass substrate, and removing a resident, uncured part of the negative photosensitive coating via a chemical solvent. Thereby, after the negative photosensitive coating is pressed, cured, and cleaned the thin film transistor is formed.

### BACKGROUND OF THE INVENTION

1. Field of the Invention

The present invention relates to a method for producing a thin film transistor, and particularly relates to a method, rather than a semiconductor process, for producing a thin film transistor.

2. Background of the Invention

A conventional method for producing a conventional thin film transistor uses semiconductor technology, which includes film deposition, photolithography technology, etching processes and the like. The film deposition process includes deposing a film of dielectric or insulative material by chemical vapor deposition (CVD) and deposing a film of electric material by physical vapor deposition (PVD). The photolithography and the etching processes define a pattern thereof. The equipment used for film deposition, photolithography and etching processes are all high-priced. As such, semiconductor technology, which consumes a lot of time and labor and requires expensive paraphernalia, is often criticized.

Referring to FIGS. 1A to 1D, the first prior art, a conventional photosensitive pressing method, illustrates a transparent plate 1a having a protrusion projected therefrom. The protrusion is transparent. A photosensitive material 3a is then poured between the transparent plate 1a and a glass substrate 2a. The transparent plate 1a and a glass substrate 2a are separated yet are close to each other. Next an ultraviolet light is provided to cure the photosensitive material 3a, which has been shaped between the transparent plate 1a and the glass substrate 2a. After a dry or wet etching process, a resident part of the photosensitive material 3a will be removed, to form a pattern of a thin film transistor. However, by this stage all parts of the photosensitive material 3a have been cured because of the transparent protrusion, so the etching process is necessary. Furthermore, the transparent protrusion still plays another role as a photoresist that controls the depth of the pattern of the thin film transistor.

FIG. 2, a perspective view of a second prior art, U.S. Pat. No. 6,518,189, discloses a first conventional nanoimprint method. An opaque plate 1b has a protrusion projected therefrom, and presses onto a layer of thermoplastic polymer materials 3b that is coated on a substrate 2b in advance. Thermoplastic polymer materials 3b, only melt at high temperatures (more than 300 degrees centigrade) and shaping requires large amounts of pressure. As such any press equipment that is used in the process should be resistant against the testing environment of these kinds of conditions. In addition, the layer of thermoplastic polymer materials 3b is cured after a cooling process and is further shaped by an etching process to produce a pattern.

With respect to FIG. 3, a perspective view of the third prior art, U.S. Pat. No. 5,900,160, discloses a first conventional microcontact method. A turbine mold 1c presses onto a substrate 2c that has a layer of micro-materials 3c in a rotating manner. This method however, lacks a precise and stable alignment. Furthermore, the mold 1c is made of Polydimethylsiloxane (PDMS) that wears out easily, deforms and has a negative effect on the precision of the pattern thereof.

The fourth prior art is displayed in FIGS. 4A to 4D which illustrate sequential perspective views as disclosed in U.S. Pat. No. 6,060,121, as a second conventional microcontact method. A plate 1d having a protrusion projected therefrom and an impression coating 3d formed thereon, presses a substrate 2d coated with a thin film 4d. Although a pattern is formed, the thickness of the pattern is much thinner that that of other conventional methods necessitating an additional process with another material in order to increase the thickness of the pattern.

The fifth prior art is displayed in FIGS. 5A to 5D which illustrate sequential perspective views as disclosed in U.S. Pat. No. 6,380,101, as a third conventional microcontact method. A plate 1e having a protrusion projected therefrom and an impression coating 3e formed thereon, presses a substrate 2e coated with a thin film 4e. Similarly to the first prior art, the impression coating 3e is further provided as a photoresist for post etching process.

The sixth prior art is displayed in FIGS. 6A to 6D which illustrate sequential perspective views as disclosed in U.S. Pat. No. 6,413,587, as a fourth conventional microcontact method. A plate if having a protrusion projected therefrom and an impression coating 3f formed thereon, presses a substrate 2f coated with a thin film 4f. Similarly to the fourth prior art, an additional process is necessary with another material in order to increase the thickness of the pattern because of the thin impression coating 3f.

In regards to the conventional microcontact methods according to the third to the sixth prior arts, the first step is to produce an impression mold made of polymer materials as the plate or mold for providing sufficient deformation in the pressing step. The impression mold should separate easily from the substrate after the pressing step. The impression mold however, often suffers from defective patterns due to the resilient property caused by the pressure that it experiences in the pressing step. So the pattern is often imprecise. Additionally, the impression mold reacts easily with non-polar organic solvents, such as toluene or hexane. When this occurs, the impression mold expands by a volume thereof due to its chemical property. As such, the peripheral environment should be controlled and monitored.

Hence, an improvement over the prior art is required to overcome the disadvantages thereof.

### SUMMARY OF INVENTION

The primary objective of the invention is therefore to specify a thin film transistor that can replace the conventional semiconductor process with simple steps, thereby improving manufacturing efficiency and saving on production costs.

The secondary objective of the invention is therefore to specify a thin film transistor that can adjust the depth of a desired pattern directly, without additional etching or other processes.

According to the invention, these objectives are achieved by a method for producing a thin film transistor and include the following steps—preparing a glass substrate; having a negative photosensitive coated on the glass substrate; providing a transparent mold plate, having a plurality of opaque protrusions in accordance with a predetermined pattern; controlling the transparent mold plate closely thereby pressing into the negative photosensitive coating of the glass substrate; curing a part of the negative photosensitive coating, which is then shielded by the protrusions and shaped according to the predetermined pattern, via an explosion of UV light; separating the transparent mold plate from the glass substrate, and removing a resident, uncured part of the negative photosensitive coating via a chemical solvent. Thereby, after the negative photosensitive coating is pressed, cured, and cleaned, the thin film transistor is formed.

According to the invention, these objectives are achieved by a thin film transistor that includes a glass substrate having a negative photosensitive coating formed thereon and a transparent mold plate including a plurality of opaque protrusions disposed thereon. A part of the negative photosensitive coating is unshielded via the protrusions and cured to correspond to a predetermined pattern; the opaque protrusions are also arranged relevant to the predetermined pattern. The part of the negative photosensitive coating is shaped via a UV light, while a resident part of the negative photosensitive coating shielded by the opaque protrusions is removed via a chemical solvent. Whereby the thin film transistor is formed, after the negative photosensitive coating is pressed, cured, and cleaned.

According to the invention, these objectives are achieved by a thin film transistor that includes a glass substrate having a negative photosensitive coating formed thereon, a transparent mold plate including a plurality of opaque protrusions disposed thereon, and an adhesion layer formed between the transparent mold plate and the opaque protrusions. A part of the negative photosensitive coating is unshielded via the protrusions and cured to correspond to a predetermined pattern; the opaque protrusions are arranged relevant to the predetermined pattern, too. The adhesion layer has a coefficient of thermal expansion ranging between those of the transparent mold plate and the opaque protrusions The part of the negative photosensitive coating is shaped via a UV light while a resident part of the negative photosensitive coating shielded by the opaque protrusions is removed via a chemical solvent. Thereby, after the negative photosensitive coating is pressed, cured, and cleaned, the thin film transistor is formed.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention that will be described hereinafter and which will form the subject of the claims appended hereto.

### BRIEF DESCRIPTION OF THE DRAWINGS

These and other features, aspects, and advantages of the present invention will become better understood with regard to the following description, appended claims, and accompanying drawings, where:

FIGS. 1A to 1D are sequential perspective views according to a conventional photosensitive pressing method as the first example of prior art;

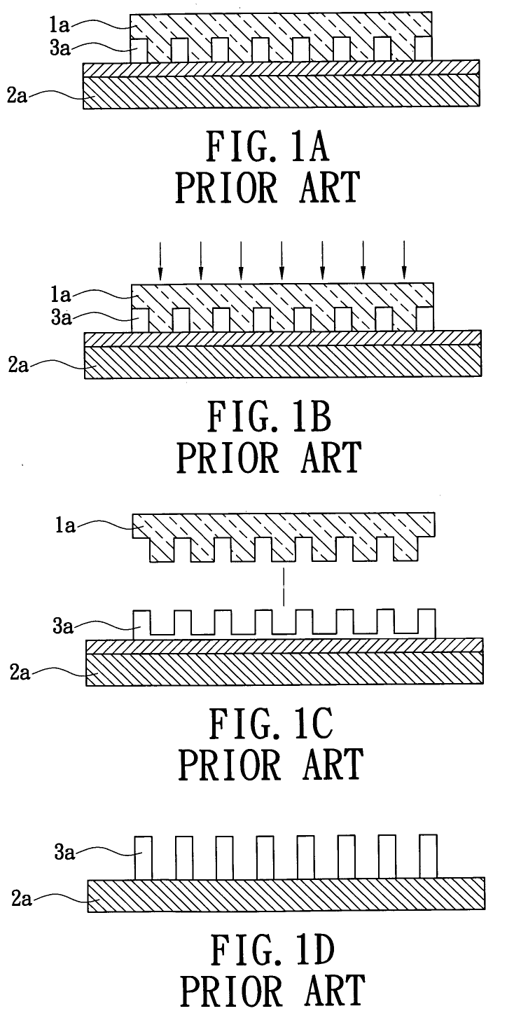

FIG. 2 is a perspective view according to a first conventional nanoimprint method patented by U.S. Pat. No. 6,518,189 as the second example of prior art;

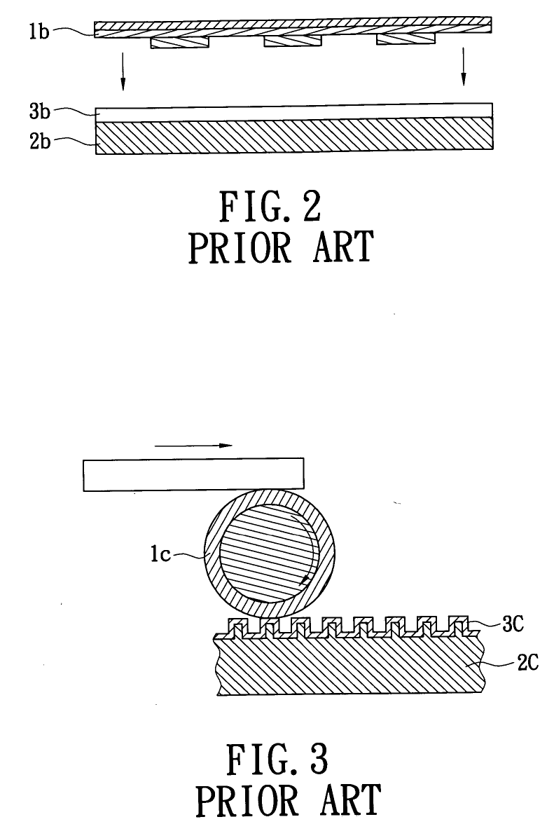

FIG. 3 is a perspective view according to a first microcontact method patented by U.S. Pat. No. 5,900,160 as the third example of prior art;

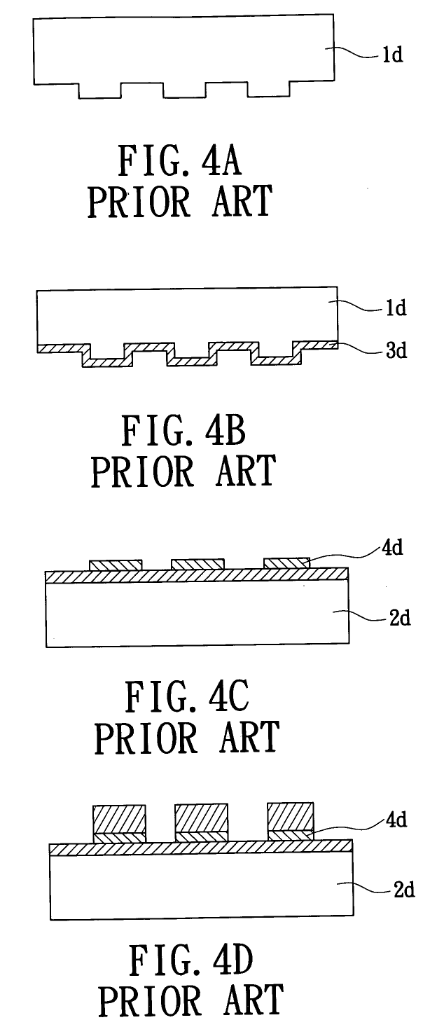

FIGS. 4A to 4D are sequential perspective views according to a second microcontact method patented by U.S. Pat. No. 6,060,121 as the fourth example of prior art;

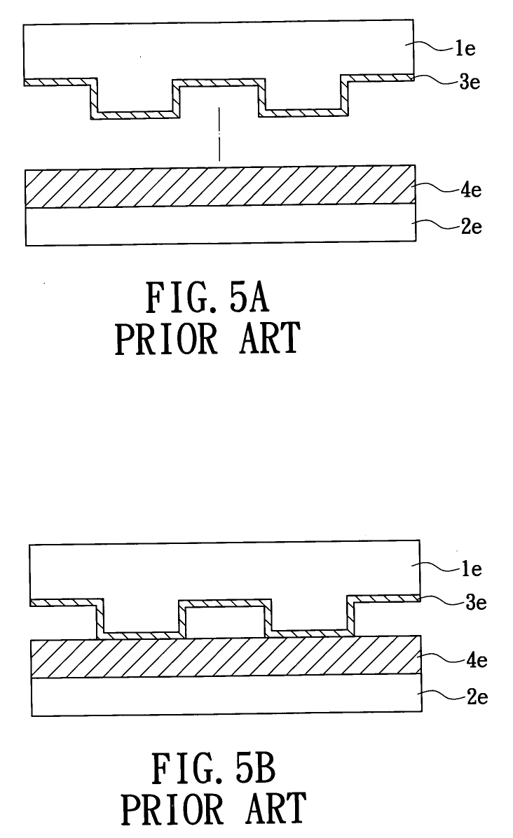

FIGS. 5A to 5D are sequential perspective views according to a third microcontact method patented by U.S. Pat. No. 6,380,101 as the fifth example of prior art;

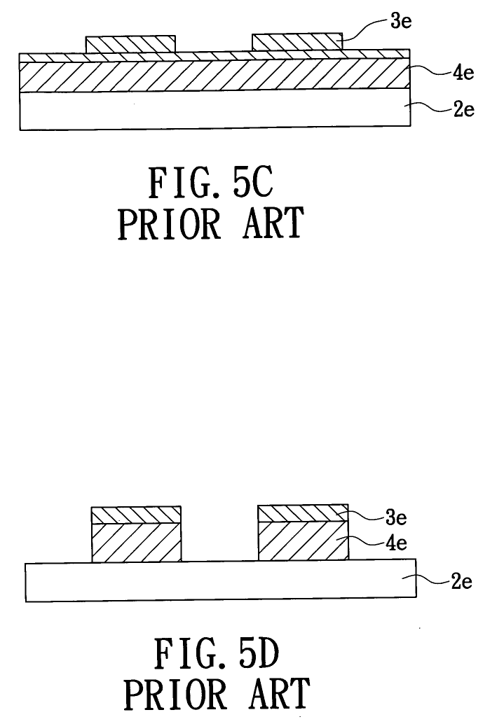

FIGS. 6A to 6D are sequential perspective views according to a fourth microcontact method patented by U.S. Pat. No. 6,413,587 as the sixth example of prior art;

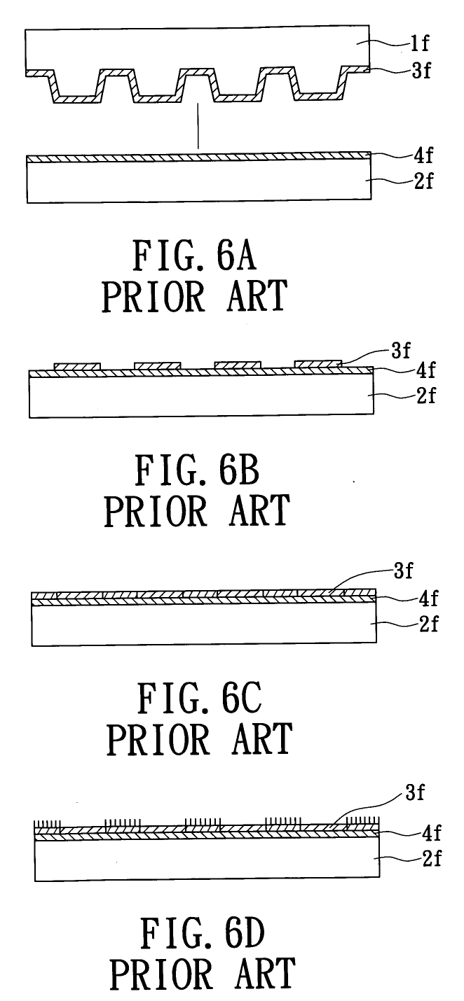

FIGS. 7A to 7C are sequential perspective views of thin film transistor of a preferred embodiment according to the present invention; and

FIG. 8 is a side view of a mold plate according to the present invention.

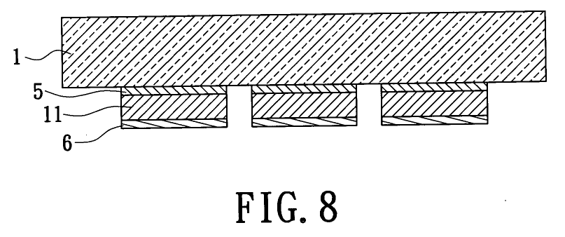

### DETAILED DESCRIPTION OF THE EMBODIMENTS

The present invention produces a plurality of opaque protrusions on a transparent mold plate, and then presses the transparent mold plate onto a substrate that has a negative photosensitive coating formed in advance. The opaque protrusions can shield a part of the negative photosensitive coating and prevent curing from a UV light, thus removing the uncured part via a chemical solvent to define both a predetermined pattern and a depth of the predetermined pattern simultaneously without additional etching or other processes. The method according to the present invention can be brought into practice to each layer of a thin film transistor by taking different photosensitive materials with specific properties; for example, a semiconductor photosensitive material can be used as a semiconductor layer and the like, such as active layer or an ohmic contact layer; a conductive material can be used as a conductive line or a electrode layer, such as a gate electrode, a source electrode, a drain electrode, a contact pad, a capacitance electrode, a circuit line and so on; an insulative material is used for isolation, such as an insulator layer, a dielectric layer or a passivation layer. These layers mentioned above need more steps if produced by a conventional semiconductor process. These additional steps ensure that the method according to the present invention is effective and that the expensive equipment that the conventional semiconductor process needs are not required.

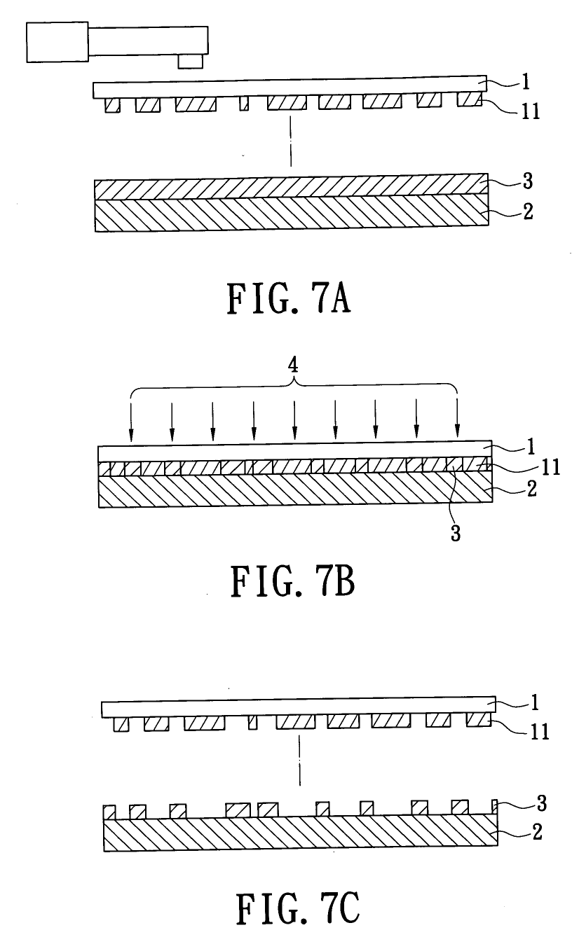

With respect to FIGS. 7A to 7C, a method for producing a thin film transistor of sequential perspective views according to the present invention includes the following steps. Firstly, preparing a glass substrate 2 prior to providing a negative photosensitive coating 3 on the glass substrate 2 in a spin-coating manner as shown in FIG. 7A. Secondly, providing a transparent mold plate 1, which then has a plurality of opaque protrusions 11 in accordance with a predetermined pattern. Thirdly, in FIG. 7B, the transparent mold plate 1 is controlled to press closely to the negative photosensitive coating 3 of the glass substrate 2 with uniform pressure. The negative photosensitive coating 3 is a kind of fluid, so that the negative photosensitive coating 3 is forced with a predetermined depth by the opaque protrusions 11 and flows to fill a space between the transparent mold plate 1 and the glass substrate 2. A part of the negative photosensitive coating 3, which is not shielded under the opaque protrusions 1, is cured to shape corresponding to the pattern via an explosion by a UV light 4. FIG. 7C shows that a resident part of the negative photosensitive coating 3, which is shielded under the opaque protrusions 1 and not cured thereby, is removed via a chemical solvent, after the transparent mold plate 1 is separated from the glass substrate 2. Therefore, the negative photosensitive coating 3 is finally formed with the predetermined pattern. The negative photosensitive coating 3 can be made of semiconductor, conductive or insulating materials. The thin film transistor is formed after the negative photosensitive coating 3 is pressed, cured, and cleaned in a sequential manner. The transparent mold plate 1 is made of glass material or quartz; the opaque protrusions 11 are made of metallic material, such as Cr, Mo or W. At this stage the height of the opaque protrusions 11 are a little less than their required height at the end of the process.

The transparent mold plate 1 is cleaned by part of the conventional semiconductor process. Furthermore, the transparent mold plate 1 can be deposed with an adhesion layer 5 (a kind of a metallic oxide) prior to being disposed with the protrusions 11 (a kind of a metallic thin film) wherein the adhesion layer 5 has a coefficient of thermal expansion ranging between those of the transparent mold plate 1 and the opaque protrusions 11. The adhesion layer 5 is made of a metallic oxide that is made from a predetermined metal. The predetermined metal is one of the transition metals, which includes Cr, Mo or W; and the metallic oxide is a transition-metal oxide corresponding to the predetermined metal. According to a proffered embodiment, the transparent mold plate 1 is deposed with a chromium oxide, which has a thickness of less than 500 Å. The transparent mold plate 1 with the chromium oxide is then further deposited with a layer of chromium (Cr). The layer of chromium has a real thickness a little less than the anticipated predetermined depth of the predetermined pattern, and a difference, between the real thickness and the anticipated depth, exists due to the forcing pressure of the transparent mold plate 1 and properties of viscosity of the opaque protrusions 11 and the negative photosensitive coating 3. The difference should be within or no more than 10%. The layer of the protrusions 11, the metallic thin film, and the layer of adhesion layer 5, metallic oxide, are further processed by photo and etching processes (like dryetching, wet etching, using an E-beam process or laser writing) simultaneously, so as to form as a plurality of the protrusions 11 corresponding to the predetermined pattern. After the protrusions 11 are defined, a transparent material (like Teflon) will be deposed onto a surface each of the protrusions 11. Because Teflon is de-wetted from the negative photosensitive coating 3, Teflon is called a dewetting layer 6.

An image sensor is provided in order to align with both of the transparent mold plate 1 and the glass substrate 2. The image sensor is a charge coupled device (CCD) and complementary metal-oxide semiconductor (CMOS) selectively.

Advantages of the present invention are summarized as follows:
1. To replace the conventional semiconductor process with simple steps, so as to improve efficiency and save on production costs.

2. To adjust the predetermined depth of the desired pattern directly with the chemical solvent, without additional etching or other processes; this will also lower costs.

3. The method can be practiced in each layer of the thin film transistor.

4. The protrusions are made of metal materials with rare deformation, so they are more precise and accurate.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A method for producing a thin film transistor comprising:
preparing a glass substrate;
having a negative photosensitive coating on the glass substrate;
providing a transparent mold plate, which has a plurality of opaque protrusions arranged in accordance with a predetermined pattern;
controlling the transparent mold plate closely to press into the negative photosensitive coating of the glass substrate;
curing a part of the negative photosensitive coating, which is adjacent to the opaque protrusions and shaped corresponding to the pattern, via an explosion by a UV light; and
separating the transparent mold plate from the glass substrate, and removing a resident part of the negative photosensitive coating, which is shielded under the opaque protrusions and not cured, via a chemical solvent;
whereby the thin film transistor is formed, after the negative photosensitive coating made from changeable material is pressed, cured, and cleaned.

2. The method for producing the thin film transistor as claimed in claim 1, further including a step of providing the negative photosensitive coating in a spin-coating manner.

3. The method for producing the thin film transistor as claimed in claim 1, wherein the part of the negative photosensitive coating is forced with a predetermined depth by the transparent mold plate.

4. The method for producing the thin film transistor as claimed in claim 1, wherein the negative photosensitive coating is made of semiconductor, conductive or insulating materials.

5. The method for producing the thin film transistor as claimed in claim 1, wherein the transparent mold plate is made of glass material or quartz and the opaque protrusions are made of metallic materials.

6. The method for producing the thin film transistor as claimed in claim 5, further including a step of arranging an adhesion layer between the transparent mold plate and the opaque protrusions; wherein the adhesion layer has a coefficient of thermal expansion ranging between those of the transparent mold plate and the opaque protrusions.

7. The method for producing the thin film transistor as claimed in claim 6, wherein the adhesion layer is made of a metallic oxide that is made from a predetermined metal.

8. The method for producing the thin film transistor as claimed in claim 7, wherein the predetermined metal, such as Cr, Mo or W; and the metallic oxide is a transition-metal oxide corresponding to the predetermined metal.

9. The method for producing the thin film transistor as claimed in claim 5, further including a step of arranging a dewetting layer, which is de-wetted from the negative photosensitive coating, onto the metallic material.

10. The method for producing the thin film transistor as claimed in claim 9, wherein the dewetting layer is made from Teflon.

11. The method for producing the thin film transistor as claimed in claim 1, further including a step of providing an image sensor in order to align with both the transparent mold plate and the glass substrate.

12. The method for producing the thin film transistor as claimed in claim 11, wherein the image sensor is a charge coupled device (CCD) or complementary metal-oxide semiconductor (CMOS).

13. A thin film transistor using the method claimed in claim 1, comprising:
a glass substrate having a negative photosensitive coating formed thereon, and a part of the negative photosensitive coating being cured corresponding to a predetermined pattern; and
a transparent mold plate including a plurality of opaque protrusions disposed thereon, and the opaque protrusions being arranged relevant to the predetermined pattern;
wherein the part of the negative photosensitive coating is shaped via a UV light while a resident part of the negative photosensitive coating shielded by the opaque protrusions is removed via a chemical solvent;
whereby the thin film transistor is formed, after the negative photosensitive coating is pressed, cured, and cleaned.

14. The thin film transistor as claimed in claim 13, wherein the negative photosensitive coating is made of semiconductor, conductive or insulating materials in a selective manner.

15. The thin film transistor as claimed in claim 13, wherein the transparent mold plate is made of glass materials or quartz; the opaque protrusions are made of metallic materials.

16. The thin film transistor as claimed in claim 15, further including an adhesion layer formed between the transparent mold plate and the opaque protrusions; wherein the adhesion layer has a coefficient of thermal expansion ranging between those of the transparent mold plate and the opaque protrusions.

17. The thin film transistor as claimed in claim 16, wherein the adhesion layer is made of a metallic oxide that is made from a predetermined metal.

18. The thin film transistor as claimed in claim 17, wherein the predetermined metal is a transition metal, such as Cr, Mo or W; and the metallic oxide is a transition-metal oxide corresponding to the predetermined metal.

19. The thin film transistor as claimed in claim 13, further including a dewetting layer, which is de-wetted from the negative photosensitive coating, arranged onto the metallic material.

20. The thin film transistor as claimed in claim 19, wherein the dewetting layer is made from Teflon.

21. A thin film transistor using the method claimed in claim 1, comprising:
a glass substrate having a negative photosensitive coating formed thereon, and a part of the negative photosensitive coating being cured corresponding to a predetermined pattern;
a transparent mold plate including a plurality of opaque protrusions disposed thereon, and the opaque protrusions being arranged relevant to the predetermined pattern; and
an adhesion layer formed between the transparent mold plate and the opaque protrusions; and the adhesion layer having a coefficient of thermal expansion ranging between those of the transparent mold plate and the opaque protrusions;
wherein the part of the negative photosensitive coating is shaped via a UV light while a resident part of the negative photosensitive coating shielded by the opaque protrusions is removed via a chemical solvent;
whereby the thin film transistor is formed, after the negative photosensitive coating is pressed, cured, and cleaned.

22. The thin film transistor as claimed in claim 21, wherein the negative photosensitive coating is made of semiconductor, conductive or insulating materials.

23. The thin film transistor as claimed in claim 21, wherein the transparent mold plate is made of the glass materials or quartz; the opaque protrusions are made of metallic materials.

24. The thin film transistor as claimed in claim 23, wherein the adhesion layer is made of a metallic oxide that is made from a predetermined metal.

25. The thin film transistor as claimed in claim 24, wherein the predetermined metal is a transition metal, such as Cr, Mo or W; and the metallic oxide is a transition-metal oxide corresponding to the predetermined metal.

26. The thin film transistor as claimed in claim 24, further including a dewetting layer, which is de-wetted from the negative photosensitive coating, arranged onto the metallic materials.

27. The thin film transistor as claimed in claim 26, wherein the dewetting layer is made from Teflon.
